(19) United States
(12) Patent Application Publication
(10) Pub. No.: US 2009/0206055 A1
(43) Pub. Date: Aug. 20, 2009

(54) PLASMA PROCESSING APPARATUS AND METHOD, AND BAFFLE PLATE OF THE PLASMA PROCESSING APPARATUS

(75) Inventors: Tetsuji SATO, Nirasaki City (JP); Akihiro Yoshimura, Nirasaki City (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/388,843

(22) Filed: Feb. 19, 2009

Related U.S. Application Data
(60) Provisional application No. 61/055,577, filed on May 23, 2008.

(30) Foreign Application Priority Data
Feb. 20, 2008 (JP) 2008-039374

(51) Int. Cl. H01L 21/306

(52) U.S. Cl. 216/58; 204/298.33; 204/298.31

(57) ABSTRACT

In a plasma processing apparatus for performing a plasma process on a target substrate, a baffle plate has an opening through which the process passes and partitions the internal space of the processing container into a plasma process space and an exhaust space, the opening being a single continuous slit. The baffle plate is disposed in an annular gas exhaust path around the mounting table, and the slit includes a plurality of linear slit portions extending in a radial direction of the annular baffle plate and a plurality of curved slit portions, each of which interconnects ends of a pair of the adjacent linear slit portions, so that the slit is formed in a wave shape in its entirety.

### FIELD OF THE INVENTION

The present invention relates to a plasma processing apparatus and method for performing an etching process or a film forming process on a target substrate such as a substrate for a semiconductor device or a liquid crystal display (LCD), and a baffle plate disposed in a gas exhaust path of the plasma processing apparatus.

### BACKGROUND OF THE INVENTION

A plasma processing apparatus is used for dry etching and the like typically used in a process of manufacturing semiconductor devices. The plasma processing apparatus introduces a gas into a processing chamber and excites the gas with high frequency waves, microwave or the like, and generate plasma to produce radicals and ions. Then, the radicals and ions generated by the plasma react with a target substrate to be processed and a reaction product, which is a volatile gas, is exhausted to the outside by a vacuum exhaustion system.

The processing chamber of the plasma processing apparatus is provided, on its top side, with an inlet through which a process gas is introduced into the processing chamber. The processing container includes therein a mounting table on which the target substrate is mounted. In a plasma processing apparatus of a parallel flat plate type, the mounting table also serves as a lower electrode. An annular gas exhaust path is formed between the mounting table and an inner wall of the processing chamber. The processing chamber is provided, on its bottom side, with a gas exhaust port through which reaction gas passed through the annular gas exhaust path is exhausted.

An annular baffle plate for partitioning the internal space of the processing chamber into a process space and an exhaust space is disposed in the annular gas exhaust path of the processing chamber. The baffle plate has openings through which gas passes. The baffle plate serves to confine plasma in the process space and exhaust the reaction gas above the mounting table uniformly in a circumference direction, irrespective of a position of the gas exhaust port.

Specifically, in many cases, the gas exhaust port is disposed at a position deviated from the center of the processing chamber. In this condition, when the processing chamber is evacuated to a vacuum, a pressure gradient is generated above the target substrate, thereby making a distribution of radicals and ions nonuniform. Such a pressure gradient above the target substrate causes irregularity of an etching rate. The baffle plate acts as resistance to flow of the process gas to alleviate the pressure gradient.

The openings of the baffle plate are typically formed as a plurality of holes of Φ1.5 to Φ5 mm (see Japanese Patent Laid-open Publication No. 2003-249487, e.g., FIG. 4). Besides the holes, a plurality of slits radially extending from the center of the annular baffle plate and a plurality of arc-like slits circumferentially extending to the annular baffle plate have been known (see Japanese Patent Laid-open Publication No. 2000-188281, e.g., FIGS. 2 and 11).

When exhaust performance (P-Q characteristic) of the plasma processing apparatus is improved and the residence time of the process gas is made shortened, an etching rate may be increased. This is because etching is carried out by dissociating the process gas by means of plasma.

However, in the plasma processing apparatus provided with the above-mentioned conventional baffle plate having the holes or slits, a conductance of the baffle plate is a predominant factor in calculating the exhaust performance (P-Q characteristic) of the plasma processing apparatus. Although there is an attempt to lower the internal pressure of the processing chamber to increase a gas flow rate, the conductance of the baffle plate remains in a rate controlling step, which makes it impossible to put the processing chamber under reduced pressure. The term “conductance” as used herein refers to a division of the amount of gas flowing through the baffle plate by a pressure difference, which is used as an indicator showing how easily a gas flows. A greater conductance may give the more amount of gas flow for the same pressure difference.

Although the conductance of the baffle plate may be increased when diameter of holes or width of slits is increased, this may cause a significant plasma leakage problem.

### SUMMARY OF THE INVENTION

In view of the above, the present invention provides a plasma processing apparatus which is capable of preventing plasma leakage and increasing a conductance of a baffle plate, and a baffle plate of the plasma processing apparatus.

In accordance with an aspect of the present invention, there is provided a plasma processing apparatus for performing a plasma process on a target substrate, including: a processing chamber into and from which the target substrate is loaded and unloaded; a mounting table provided within the processing container, the target substrate being mounted on the mounting base; an inlet through which a process gas is introduced into the processing container; a radio frequency power supply for exciting the process gas in the processing container to generate plasma; a gas exhaust hole through which the process gas is exhausted out of the processing container; and a baffle plate having an opening through which the process passes and partitioning the internal space of the processing container into a plasma process space and an exhaust space, the opening being a single slit.

Preferably, the baffle plate is disposed in an annular gas exhaust path around the mounting base, and the slit includes a plurality of linear slit portions extending in a radial direction of the annular baffle plate and a plurality of curved slit portions, each of which interconnects ends of a pair of adjacent linear slit portions, so that the slit is formed in a wave shape in its entirety.

Preferably, the baffle plate includes a first member having a first ring-shaped body portion and a plurality of first projections projecting outwardly from the first ring-shaped body portion; and a second member having a second ring-shaped body portion larger in diameter than the first ring-shaped body portion of the first member and a plurality of second projections projecting inwardly from the second ring-shaped body portion, wherein the slit is formed between the first member and the second member.

Preferably, a reinforcing member is arranged between the first member and the second member.

Preferably, each of the first and second members is formed with a plurality of sectorial members.

Preferably, the baffle plate is disposed in an annular gas exhaust path around the mounting base, and the slit is formed in a spiral shape extending in a circumference direction along the annular baffle plate.

Preferably, an aspect ratio of thickness to width of the slit (slit thickness/slit width) is set to be 2 to 8.

In accordance with another aspect of the present invention, there is provided a baffle plate of a plasma processing apparatus in which a process gas is introduced into a processing chamber, plasma is generated by exciting the process gas in the processing chamber using radio frequency power, and the process gas is exhausted out of the processing chamber, the baffle plate partitioning the internal space of the processing chamber into a process space and an exhaust space, wherein an opening of the baffle plate through which the process gas passes is a single continuous slit.

In accordance with still another aspect of the present invention, there is provided a baffle plate of a plasma processing apparatus in which a process gas is introduced into a processing container, plasma is generated by exciting the process gas in the processing chamber using radio frequency power, and the process gas is exhausted out of the processing chamber, the baffle plate partitioning the internal space of the processing chamber into a process space and an exhaust space, wherein the baffle plate is disposed in an annular gas exhaust path around a mounting table on which a target substrate is mounted, and wherein an opening of the baffle plate through which the process gas passes is a slit including a plurality of linear slit portions extending in a radial direction of the annular baffle plate and a plurality of curved slit portions, each of which interconnects ends of a pair of the adjacent linear slit portions, the slit being formed in a wave shape in its entirety.

In accordance with still another aspect of the present invention there is provided a baffle plate of a plasma processing apparatus in which a process gas is introduced into a processing chamber, plasma is generated by exciting the process gas in the processing chamber using radio frequency power, and the process gas is exhausted out of the processing chamber, the baffle plate partitioning the internal space of the processing plate into a process space and an exhaust space, wherein the baffle plate is disposed in an annular gas exhaust path around a mounting table on which a target substrate is mounted, and wherein an opening of the baffle plate through which the process gas passes is a slit which is formed in a spiral shape extending in a circumference direction along the annular baffle plate.

In accordance with still another aspect of the present invention there is provided a plasma processing method for performing a plasma process on a target substrate, including: introducing a process gas into a processing chamber through an inlet, the target substrate being placed within the processing chamber; generating plasma by exciting the process gas in the processing chamber using radio frequency power; and exhausting the process gas out of the processing chamber through a gas exhaust port via a baffle plate having an opening of a single continuous slit and partitioning the internal space of the processing chamber into a plasma process space and an exhaust space.

For the same opening area, the slit which connects a plurality of holes has a larger conductance of the baffle plate than the holes. For example, a single slit having an area of 5 mm² has a larger conductance than 10 holes each having an area of 0.5 mm². When the baffle plate is formed with a plurality of holes, gas particles are reflected from walls between the holes and thus are hard to pass through the holes. When the slit is made by connecting the plurality of holes, the walls between the holes disappear and the gas particles can pass through the slit easily.

In the same manner, for the same opening area, a single slit, a wave-shaped slit or a spiral slit formed by connecting a plurality of slits has a larger conductance of the baffle plate than a plurality of slits. This is because walls between the slits can be reduced.

In addition, since plasma leakage has a relation to an aspect ratio (slit thickness/slit width), a single slit formed by the plurality of slits can prevent the plasma leakage from being increased.

### BRIEF DESCRIPTION OF THE DRAWINGS

The objects and features of the present invention will become apparent from the following description of embodiments, given in conjunction with the accompanying drawings, in which:

FIG. 1 is a schematic view of a plasma processing apparatus in accordance with an embodiment of the present invention;

FIG. 2 is a perspective view of a baffle plate of the plasma processing apparatus;

FIG. 3 is a plan view of the baffle plate of the plasma processing apparatus;

FIG. 4 is a plan view of another exemplary baffle plate of the plasma processing apparatus;

FIGS. 5A and 5B are partial perspective views of a conventional baffle plate and an inventive baffle plate having a wave-shaped slit, respectively, for comparison therebetween;

FIGS. 6A and 6B are partial plan views of the conventional baffle plate and the inventive baffle plate having the wave-shaped slit, respectively, for comparison therebetween;

FIGS. 7A and 7B are partial plan views of the conventional baffle plate and another inventive baffle plate having a spiral slit, respectively, for comparison therebetween;

FIG. 8 is a graph showing a P-Q characteristic of the plasma processing apparatus; and

FIG. 9 is a graph showing a P-Q characteristic of the plasma processing apparatus when an aspect ratio of slit of the baffle plate is changed.

### DETAILED DESCRIPTION OF THE EMBODIMENTS

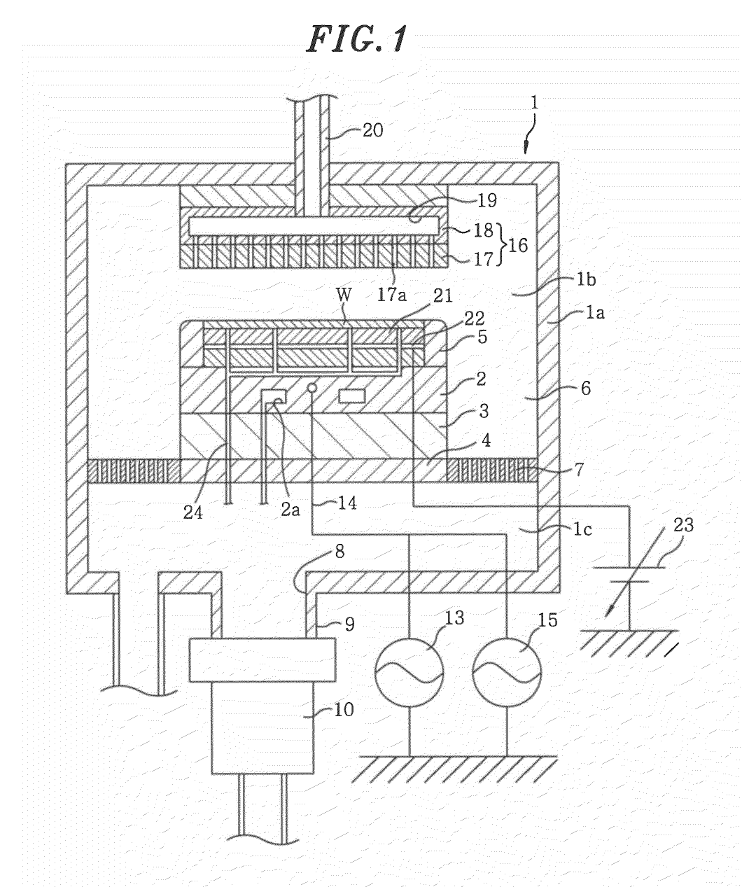

Hereinafter, a plasma processing apparatus in accordance with an exemplary embodiment of the present invention will be described with reference to the accompanying drawings. FIG. 1 schematically shows an overall configuration of a plasma processing apparatus (etching apparatus).

In FIG. 1, reference numeral “1” denotes a cylindrical chamber as a processing chamber. As shown, an axial end portion of the chamber 1 is closed so that the chamber 1 is made airtight. A side wall la of the chamber 1 is provided with a loading/unloading port (not shown) through which a target substrate to be processed is loaded into and unloaded from the chamber 1, respectively. The loading/unloading port is opened/closed by a gate valve. When the target substrate is loaded into or unloaded from the chamber 1, the gate valve opens the loading/unloading port. The chamber 1 is made of a material such as aluminum, stainless steel or the like. The chamber 1 is grounded to the earth.

Inside the chamber 1, there is provided a susceptor 2 as a mounting table on which the target substrate, such as a semiconductor wafer W, is mounted. The susceptor 2 is made of a conductive material such as aluminum or the like and also serves as a lower electrode. The susceptor 2 is supported by a disc-like holder 3 which is made of an insulating material such as ceramic or the like. The disc-like holder 3 is supported by a disc-like supporter 4 of the chamber 1. On the susceptor 2, there is disposed an annular focus ring 5 made of a material such as quartz, Si or the like.

An annular gas exhaust path 6 is formed between the susceptor 2 and the side wall 1a of the chamber 1. An annular baffle plate 7 is disposed at a lower portion of the gas exhaust path 6. The baffle plate 7 partitions the inner space of the chamber 1 into a plasma processing space (discharge space) 1b and an exhaust space 1c. A structure of the baffle plate will be described in detail later.

In the bottom of the chamber 1, there is provided a gas exhaust port 8 through which a process gas is exhausted. The gas exhaust port 8 is connected with a gas exhaust unit 10 via a gas exhaust pipe 9. The gas exhaust unit 10 includes a vacuum pump and reduces the internal pressure of the plasma processing space 1b within the chamber 1 to a predetermined degree of vacuum. A radio frequency (RF) power supply 13 for plasma generation is electrically connected to the susceptor 2 via a matching unit and a power feed rod 14. The RF power supply 13 supplies a high frequency (HF) RF power of, e.g., 40 MHz to the susceptor 2, i.e., the lower electrode. In addition, a RF power supply 15 for a bias to attract radicals and ions in plasma to the semiconductor wafer W is connected to the susceptor 2 via the matching unit and the power feed rod 14. The RF power supply 15 supplies a low frequency (LF) RF power of, e.g., 12.88 MHz, 3.2 MHz and so on to the susceptor 2. At the ceiling of the chamber 1, there is provided a shower head 16 as an upper electrode. The shower head 16 at the ceiling includes a lower electrode plate 17 having a plurality of inlets 17a and an upper electrode support 18 for detachably holding the electrode plate 17. A process gas is introduced into the chamber 17a through the inlets 17a. A buffer space 19 is formed inside the electrode holder 18. A gas supplying pipe 20 extending from a process gas supplying unit is connected to the buffer space 19.

The shower head 16 is disposed to face the susceptor 2 in parallel and is grounded to the earth. As mentioned above, the shower head 18 and the susceptor 2 function as a pair of electrodes, that is, the upper electrode and the lower electrode, respectively. When the RF power supply 13 applies high frequency RF power between the shower head 16 and the susceptor 2, the process gas introduced therebetween is excited, thereby producing the plasma. The low frequency RF power attracts radicals and ions in the plasma to the semiconductor wafer W.

On the susceptor 2, there is provided an electrostatic chuck 21 which generates an electrostatic attraction force to hold the semiconductor wafer W. The electrostatic chuck 21 is made of a dielectric material such as ceramic or the like. The electrostatic chuck 21 has therein a conductive high voltage (HV) electrode 22. The HV electrode 22 is made of a conductive material such as, for example, copper, tungsten or the like.

A DC power supply 23 is electrically connected to the HV electrode 22. The DC power supply 23 applies a plus or minus DC voltage of 2500 V, 3000 V or the like to the HV electrode 22. When the DC power supply 23 applies such a DC voltage to the HV electrode 22, the semiconductor wafer W is attracted and held on the electrostatic chuck 21 by a Coulomb force.

The susceptor 2 has therein an annular coolant channel 2a extending in a circumferential direction, for example. A pipe is connected to the coolant channel 2a. A chiller unit (not shown) circulates a coolant, e.g., cooling water, of a predetermined temperature. By controlling the temperature of the coolant, it is possible to control process temperature of the semiconductor wafer W on the electrostatic chuck 21.

A heat transfer gas, such as He gas, from a heat transfer gas supplying unit is introduced between the top side of the electrostatic chuck 21 and the back side of the semiconductor wafer W via a gas supplying pipe 24. The top side of the electrostatic chuck 21 and the back side of the semiconductor wafer W are not flat but uneven from a microscopic viewpoint. By introducing the heat transfer gas between the top side of the electrostatic chuck 21 and the back side of the semiconductor wafer W, thermal conductivity between the semiconductor wafer W and the electrostatic chuck 21 can be enhanced.

The operations of the gas exhaust unit 10, the RF power supplies 13 and 15, the DC power supply 23, the chiller unit and the heat transfer gas supplying unit are controlled by a controller.

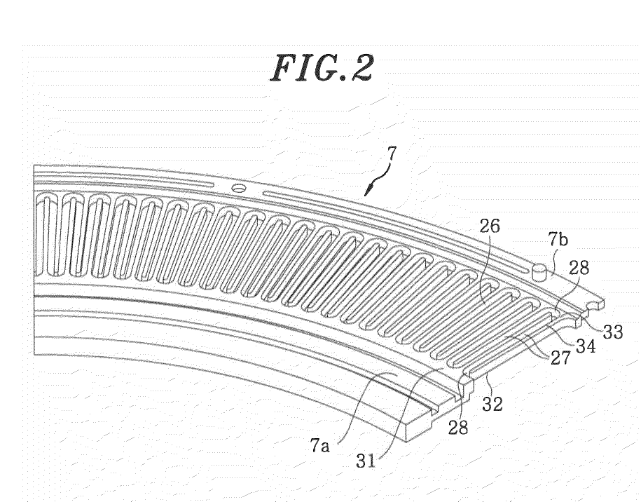

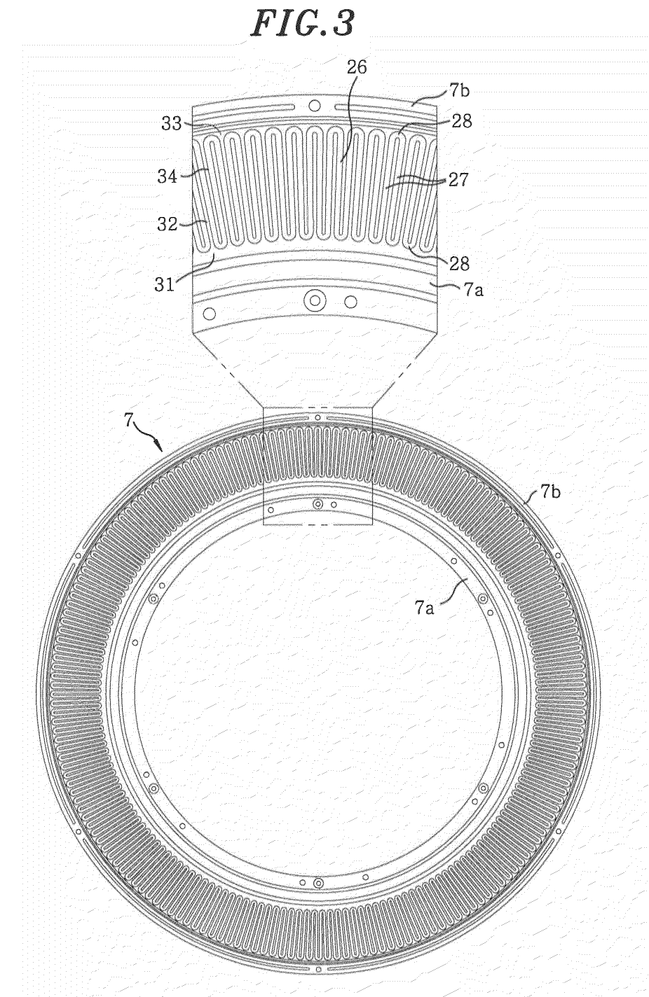

FIGS. 2 and 3 are views showing details of the baffle plate 7. FIG. 2 is a perspective view of the baffle plate 7 and FIG. 3 is a plan view of the baffle plate 7. As shown, a single continuous slit 26 is formed in the annular baffle plate 7. The slit 26 is formed into a wave shape in its entirety and includes a plurality of linear slit portions 27 extending in a radial direction of the annular baffle plate 7 and a plurality of curved slit portions 28 which interconnects the inner ends of a pair of the adjacent linear slit portions 27 and the outer ends of a pair of the adjacent linear slit portions 27. In other words, the slit 26 is extended meanderingly by in zigzags in a circumference direction. The length of slit 26 is longer than the circumferential length of the outer diameter of the baffle plate 7. An aspect ratio (ratio of thickness to width) of the slit 26 is set to be in a range of from 2 to 8.

The slit 26 is extended in an endless shape. The baffle plate 7 is therefore separated into an inner first member 7a and an outer second member 7b. The first member 7a includes a ring-shaped body portion 31 and a plurality of comb teeth 32 which are projections projecting radially outwardly from the body portion 31. The body portion 31 of the first member 7a is attached to the disc-like supporter 4 of the chamber 1.

The second member 7b includes a ring-shaped body portion 33 whose diameter is larger than that of the body portion 31 of the first member 7a and a plurality of comb teeth 34 which are projections projecting radially inwardly from the body portion 33. The body portion 33 of the second member 7b is attached to the side wall 1a of the chamber 1.

The number of comb teeth 32 of the first member 7a is equal to the number of comb teeth 34 of the second member 7b. The slit 26 is formed into a wave shape as the comb teeth 32 of the first member 7a and the comb teeth 34 of the second member 7b are combined in such an alternating manner that they make no contact with one another. As shown in this exemplary embodiment, maintainability for replacement of the baffle plate 7 can be improved by separating the baffle plate 7 into the first member 7a and the second member 7b.

In case where the baffle plate 7 is partitioned in two parts, a bridge may be placed, as a reinforcing member, between the first member 7a and the second member 7b in order to secure the strength of the baffle plate 7. This reinforcing member may used as back-up for the earth of RF power. In addition, each of the first member 7a and the second member 7b may be formed by coupling with a plurality of sectorial members which are arranged in a circumference direction.

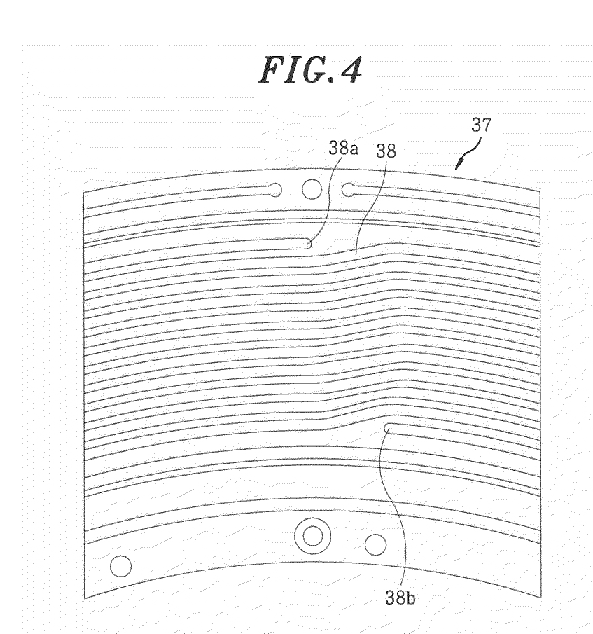

FIG. 4 shows another example of the baffle plate. This baffle plate 37 is also formed in an annular shape and it is disposed in the annular gas exhaust path 6 around the susceptor 2. The baffle plate 37 includes a spiral slit 38 extending in a circumference direction along the annular baffle plate 37. The length of the spiral slit 38 is longer than the circumference length of the peripheral edge of the baffle plate 7. The spiral slit 38 has an outer end portion 38a and an inner end portion 38b at the longitudinal ends.

If the spiral slit 38 formed in the baffle plate 37 makes it difficult to sustain the shape of the baffle plate, a bridge may be placed, as a reinforcing member, between an inner circumference and an outer circumference of the baffle plate. In addition, the reinforcing member may serve as a support for the RF earth.

An etching process using the plasma processing apparatus as structured above will be now described.

First, the gate valve provided in the chamber 1 is opened and a semiconductor wafer W is loaded into the chamber 1. When the loading is completed, the gate valve is closed and the chamber 1 is made in a vacuum state. When the semiconductor wafer W is mounted on the susceptor 2 in the chamber 1, a DC power supply 23 applies a DC voltage (HV) to the HV electrode 22. The semiconductor wafer W is attracted and held on the susceptor 2 by a Coulomb force.

Next, a process gas is introduced from the process gas supplying unit into the chamber 1 and then the RF power supplies 13 and 15 respectively apply high frequency (HF) RF power and low frequency (LF) RF power to the susceptor 2. Under such application of RF powers to the susceptor 2, plasma is generated between the shower head 16 serving as an upper electrode and the susceptor 2 serving as a lower electrode. While applying the RF power to the susceptor 2, the heat transfer gas supplying unit supplies a heat transfer gas between the back side of the semiconductor wafer W and the top side of the electrostatic chuck 21. Under this condition, an etching process for the semiconductor wafer W will start.

The RF power supplies 13 and 15 stop applying the RF powers to the susceptor 2 after a predetermined time lapses or when an end point of the etching process is detected. At the same time, the heat transfer gas supplying unit stops supplying the heat transfer gas. Next, the DC power supply 23 stops applying the DC voltage to the HV electrode 22. Thus, the semiconductor wafer W is released and then is transferred out of the chamber 1 by the transferring mechanism.

The present invention is not limited to the exemplary embodiments but may be implemented with the following different exemplary embodiments without departing from the scope of invention.

In the plasma processing apparatus of the above-described exemplary embodiments, as shown in FIG. 1, the RF powers of two frequencies, HF and LF, are applied to the susceptor 2 serving as the lower electrode. Alternatively, RF power of one frequency may be applied to the lower electrode, or RF power of LF may be applied to the lower electrode while RF power of HF is applied to the upper electrode.

In addition, the baffle plate 7 may not be disposed on a horizontal plane in the gas exhaust path and may be disposed inclined from the horizontal plane.

In addition, the openings of the baffle plate 7 may be formed in a plurality of wave-shaped slits or in a plurality of spiral slits.

The present invention is also applicable to other plasma processing apparatuses, such as plasma CVD, plasma oxidation, plasma nitriding, sputtering apparatuses and the like. The target substrate of the invention is not limited to a semiconductor wafer but may be a substrate for liquid crystal display (LCD), a photo mask and so on. The present invention is not limited to a plasma processing apparatus of a parallel flat plate type but may be applied to other plasma processing apparatuses such as ECR, ICP and the like.

### EXAMPLE

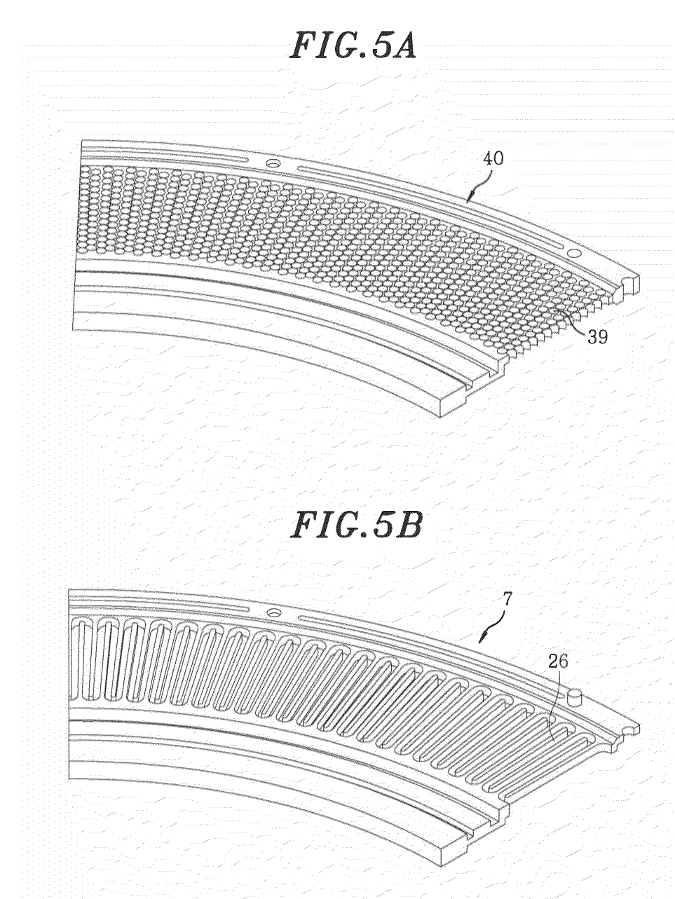

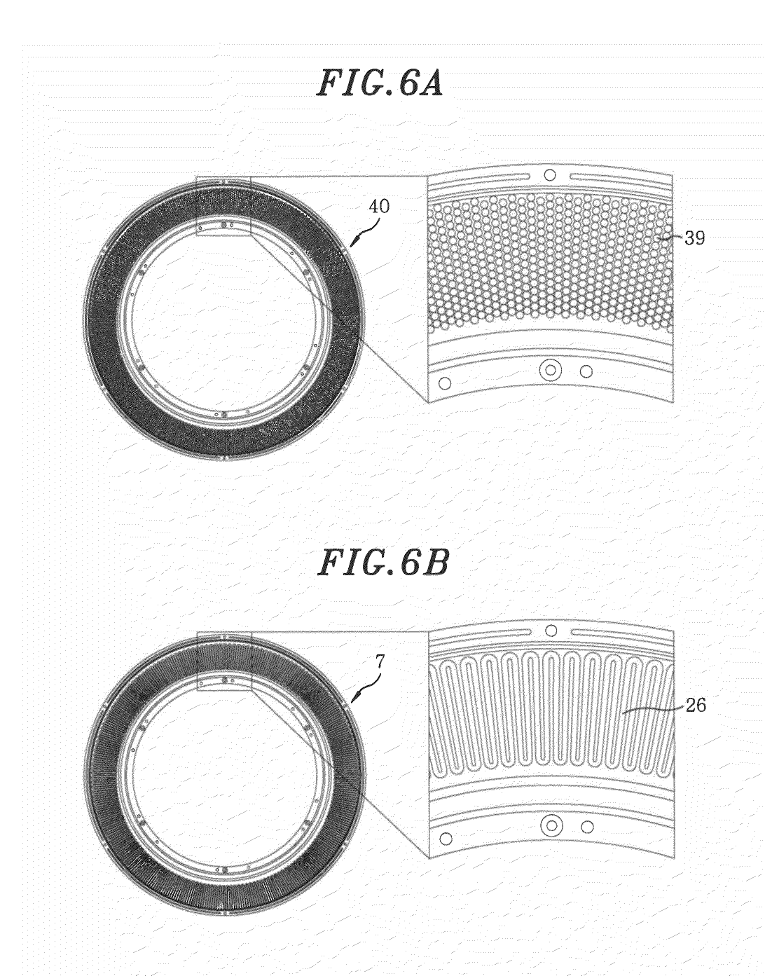

FIGS. 5A to 6B are views showing comparison of a conventional baffle plate 40 having a plurality of holes 39 formed therein with the inventive baffle plate 7 having a single wave-shaped slit 26 formed therein. Specifically, FIGS. 5A and 6A show the conventional baffle plate 40, and FIGS. 5B and 6B show the inventive baffle plate 7.

After making the external dimensions and opening areas of the baffle plates 7 and 40 equal to each other, a conductance of the conventional baffle plate 40 and a conductance of the inventive baffle plate 7 were calculated. The result of calculation is as follows.

Conductance of the conventional baffle plate 40

$$Hole diameter ( d ) \text{:} Φ 3 mm \\ Plate thickness ( t ) \text{:} 6 mm \\ Number of holes \text{:} 5 , 800 \\ Conductance calculation ( for short cylinder ) \\ t / d = 6 / 3 = 2 \to k = 0.359 \\ \begin{matrix}C 2 = k * C 1 \\ = 0.359 * ( 116 * {( ( 3 / 1000 ) / 2 )}^{\hat{}} 2 ) \\ = 2.94 e - 4 [ {m}^{3} / sec ]\end{matrix} \\ \begin{matrix}C = 5800 * C 2 \\ = 5800 * 2.94 e - 4 \\ = 1.7052 [ {m}^{3} / sec ] \\ = 1705 [ L / sec ]\end{matrix} \qquad ( Equation 1 )$$

Conductance of the inventive baffle plate 7

$$Slit width ( d ) \text{:} 3 mm \\ Plate thickness ( t ) \text{:} 6 mm \\ Slit length \text{:} 19934.68 mm \\ Conductance calculation ( for slit ) \\ t / d = 6 / 3 = 2 \to k = 0.542 \\ \begin{matrix}C = 116 * K * d * a \\ = 116 * 0.542 * ( 3 / 1000 ) * ( 19934.68 / 1000 ) \\ = 3.7599 [ {m}^{2} / sec ] \\ = 3759.9 [ L / sec ]\end{matrix} \qquad ( Equation 2 )$$

As a result of conductance calculation, while the conductance of the conventional baffle plate 40 was 1705 L/sec, the conductance of the inventive baffle plate 7 was 3759.9 L/sec. As such, the conductance of the baffle plate 7 was enhanced about two times more than the conductance of the conventional baffle plate 40 under the same opening area.

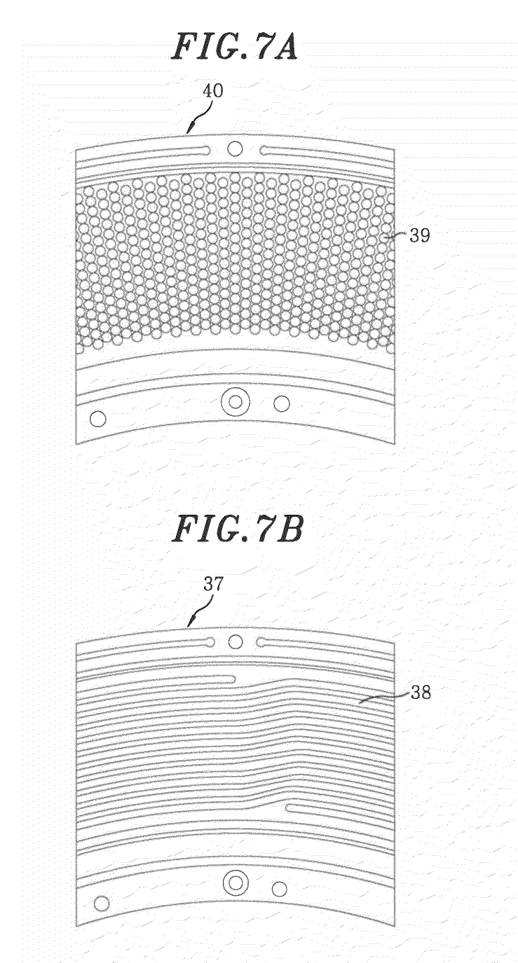

FIG. 7 is a view showing comparison of the conventional baffle plate 40 having the holes 39 with the inventive baffle plate 37 having a single spiral slit 38 formed therein. Specifically, FIG. 7A shows the conventional baffle plate 40, and FIG. 7B shows the inventive baffle plate 37.

After making the external dimensions and opening areas of the baffle plates 37 and 40 equal to each other, a conductance of the conventional baffle plate 40 and a conductance of the inventive baffle plate 37 were calculated.

Conductance of the inventive baffle plate 37

$$Slit width ( d ) \text{:} 3 mm \\ Plate thickness ( t ) \text{:} 6 mm \\ Slit length \text{:} 18829.16 mm \\ Conductance calculation ( for slit ) \\ t / d = 6 / 3 = 2 \to k = 0.542 \\ \begin{matrix}C = 116 * K * d * a \\ = 116 * 0.542 * ( 3 / 1000 ) * ( 18829.16 / 1000 ) \\ = 3.5515 [ {m}^{2} / sec ] \\ = 3551.5 [ L / sec ]\end{matrix} \qquad ( Equation 3 )$$

As a result of conductance calculation, while the conductance of the conventional baffle plate 40 1705 L/sec, the conductance of the inventive baffle plate 37 was 3551.5 L/sec. As such, the conductance of the baffle plate 37 was enhanced about two times more than the conductance of the conventional baffle plate 40 under the same opening area.

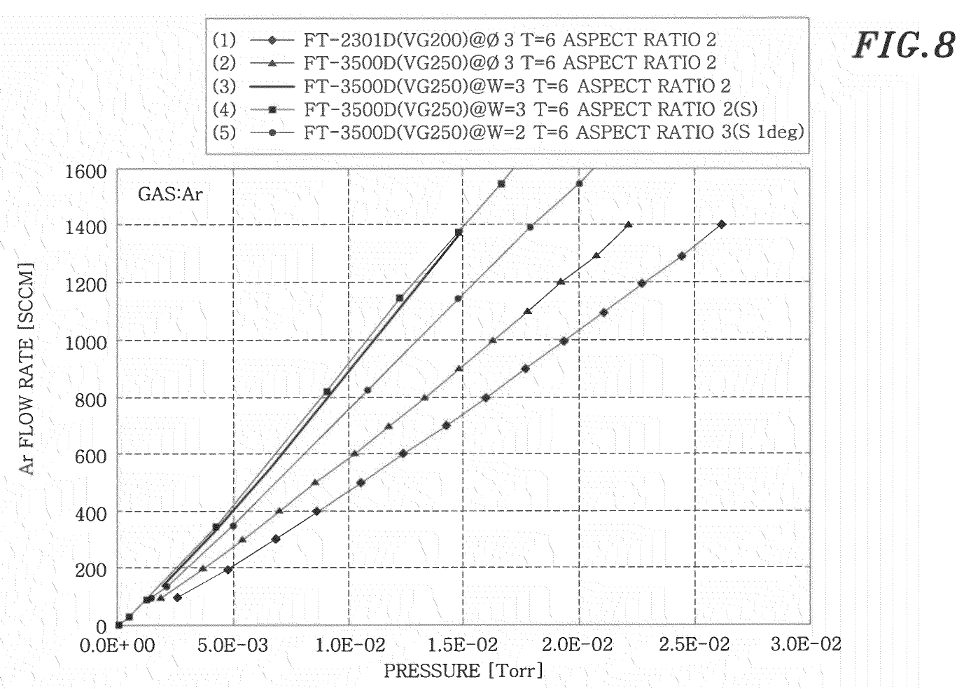

FIG. 8 is a graph showing a P-Q characteristic (a relationship between a pressure of the plasma processing space and a flow rate of Ar gas) of the plasma processing apparatus. In the graph, legends (1) and (2) denote apparatuses using the conventional baffle plate (having holes of Φ3 mm and plate thickness of 6 mm), while legends (3) to (5) denote apparatuses using the inventive baffle plate (having slit of 3 mm or 2 mm in width and plate thickness of 6 mm). In the legends, 3500D represents use of a vacuum pump of 3500L class while VG250 represents use of a flange of 250 mm caliber. The legends annexed with (S) show simulation results while the legends not annexed with (S) show results of actual measurement.

It can be seen from the graph that the inventive baffle plates having one slit formed therein (legends (3) to (5)) give better P-Q characteristics than the conventional baffle plates (legends (1) and (2)). In addition, when 1400 sccm of Ar gas is flown, for example, it can be seen that the inventive baffle plates (legends (3) and (4)) allow the plasma processing space to be set to a low vacuum of 1.5×10⁻² Torr. In contrast, when 1400 sccm of Ar gas is flown, it can be seen that the conventional baffle plate (legend (2)) shows a reduction in the degree of vacuum to 2.25×10⁻² Torr in the plasma processing space.

The slit width is set to 2 mm in the inventive baffle plate denoted by legend (5). This is because plasma leakage may occur when the slit width is large. The graph shows that the inventive baffle plate having the narrow slit of 2 mm width (legend (5)) still provides a higher degree of vacuum than of the conventional baffle plates (legend (2)).

The conventional apparatus of legend (1) uses a small vacuum pump of 2301L class. When the small vacuum pump is used, it can be seen that the P-Q characteristic of the apparatus is a little deteriorated. However, by improving a conductance of the baffle plate as shown in the exemplary embodiments of the present invention, it is possible to attain a P-Q characteristic as better as using a large vacuum pump even if a small vacuum pump is used. Miniaturization of a vacuum pump may result in miniaturization and low cost of a plasma processing apparatus.

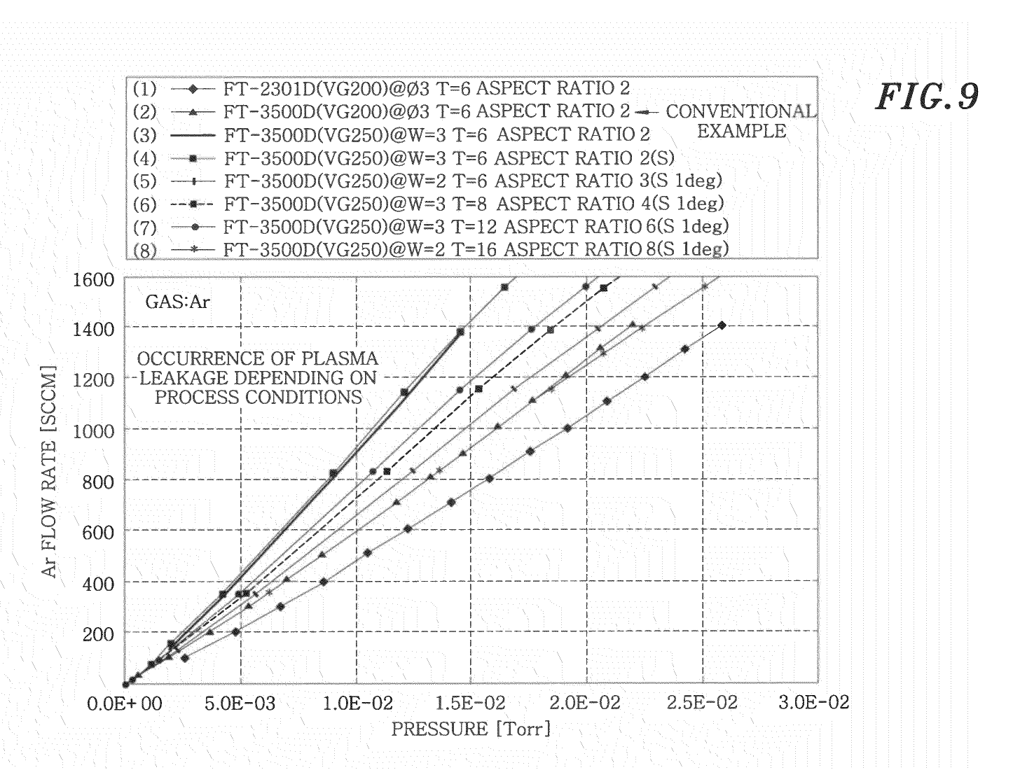

FIG. 9 is a graph showing a P-Q characteristic of a plasma processing apparatus when an aspect ratio of the slit is changed. In the graph, legends (1) and (2) denote the conventional baffle plates (having holes of Φ3 mm and plate thickness of 6 mm), while legends (3) to (5) denote the inventive baffle plates (with aspect radio of slit changed). The aspect ratio has a relation to plasma leakage. The bigger the aspect ratio, the less the plasma leakage occurs.

As shown in legend (3)s, when the aspect ratio was set to 2, plasma leakage occurred depending on the conditions of process, such as a type of gas, gas pressure, gas flow rate and the like. When the aspect ratio is set below 2, there is a problem that a process window becomes narrow. Consequently, it is preferable to set the aspect ratio to 2 or more. When the aspect ratio is set to 3 or more as shown in legends (5) to (8), the occurrence of plasma leakage can be prevented without making the process window narrow.

A P-Q characteristic for an aspect ratio of 8 as shown in legend (8) is substantially equal to a P-Q characteristic of an existing apparatus using a conventional baffle plate denoted by legend (2). A higher aspect ratio will give a lower conductance of a baffle plate. In order to achieve a better P-Q characteristic than the existing apparatus, it is desirable to set the aspect ratio to below 8.

While the invention has been shown and described with respect to the embodiments, it will be understood by those skilled in the art that various changes and modification may be made without departing from the scope of the invention as defined in the following claims.

What is claimed is:

1. A plasma processing apparatus for performing a plasma process on a target substrate, comprising:
a processing chamber into and from which the target substrate is loaded and unloaded;
a mounting table provided within the processing chamber, the target substrate being mounted on the mounting base;
an inlet through which a process gas is introduced into the processing container;
a radio frequency power supply for exciting the process gas in the processing container to generate plasma;
a gas exhaust port through which the process gas is exhausted out of the processing container; and
a baffle plate having an opening through which the process passes and partitioning the internal space of the processing container into a plasma process space and an exhaust space, the opening being a single continuous slit.

2. The plasma processing apparatus of claim 1, wherein the baffle plate is disposed in an annular gas exhaust path around the mounting table, and the slit includes a plurality of linear slit portions extending in a radial direction of the annular baffle plate and a plurality of curved slit portions, each of which interconnects ends of a pair of the adjacent linear slit portions, so that the slit is formed in a wave shape in its entirety.

3. The plasma processing apparatus of claim 1, wherein the baffle plate includes:
a first member having a first ring-shaped body portion and a plurality of first projections projecting outwardly from the first ring-shaped body portion; and
a second member having a second ring-shaped body portion larger in diameter than the first ring-shaped body portion of the first member and a plurality of second projections projecting inwardly from the second ring-shaped body portion,
wherein the slit is formed between the first member and the second member.

4. The plasma processing apparatus of claim 3, wherein a reinforcing member is arranged between the first member and the second member.

5. The plasma processing apparatus of claim 3 or 4, wherein each of the first and second members is formed with a plurality of sectorial members.

6. The plasma processing apparatus of claim 1, wherein the baffle plate is disposed in an annular gas exhaust path around the mounting base, and the slit is formed in a spiral shape extending in a circumference direction along the annular baffle plate.

7. The plasma processing apparatus of any one of claims 1 to 6, wherein an aspect ratio of thickness to width of the slit is set to be 2 to 8.

8. A baffle plate of a plasma processing apparatus in which a process gas is introduced into a processing chamber, plasma is generated by exciting the process gas in the processing chamber using radio frequency power, and the process gas is exhausted out of the processing chamber, the baffle plate partitioning the internal space of the processing chamber into a process space and an exhaust space,
wherein an opening of the baffle plate through which the process gas passes is a single continuous slit.

9. A baffle plate of a plasma processing apparatus in which a process gas is introduced into a processing container, plasma is generated by exciting the process gas in the processing chamber using radio frequency power, and the process gas is exhausted out of the processing chamber, the baffle plate partitioning the internal space of the processing chamber into a process space and an exhaust space,
wherein the baffle plate is disposed in an annular gas exhaust path around a mounting table on which a target substrate is mounted, and
wherein an opening of the baffle plate through which the process gas passes is a slit including a plurality of linear slit portions extending in a radial direction of the annular baffle plate and a plurality of curved slit portions, each of which interconnects ends of a pair of the adjacent linear slit portions, the slit being formed in a wave shape in its entirety.

10. A baffle plate of a plasma processing apparatus in which a process gas is introduced into a processing chamber, plasma is generated by exciting the process gas in the processing chamber using radio frequency power, and the process gas is exhausted out of the processing chamber, the baffle plate partitioning the internal space of the processing plate into a process space and an exhaust space,
wherein the baffle plate is disposed in an annular gas exhaust path around a mounting table on which a target substrate is mounted, and
wherein an opening of the baffle plate through which the process gas passes is a slit which is formed in a spiral shape extending in a circumference direction along the annular baffle plate.

11. A plasma processing method for performing a plasma process on a target substrate, comprising:
introducing a process gas into a processing chamber through an inlet, the target substrate being placed within the processing chamber;
generating plasma by exciting the process gas in the processing chamber using radio frequency power; and
exhausting the process gas out of the processing chamber through a gas exhaust port via a baffle plate having an opening of a single continuous slit and partitioning the internal space of the processing chamber into a plasma process space and an exhaust space.
